(19) United States
(12) Patent Application Publication
(10) Pub. No.: US 2017/0019211 A1
(43) Pub. Date: Jan. 19, 2017

(54) METHOD AND DEVICE FOR DECODING LOW DENSITY PARITY CHECK CODE FOR FORWARD ERROR CORRECTION IN WIRELESS COMMUNICATION SYSTEM

(71) Applicant: LG ELECTRONICS INC., Seoul (KR)

(72) Inventors: Kwangseok NOH, Seoul (KR); Genebeck HAHN, Seoul (KR); Jinmin KIM, Seoul (KR); Kukheon CHOI, Seoul (KR); Jaehoon CHUNG, Seoul (KR); Eunjong LEE, Seoul (KR)

(73) Assignee: LG ELECTRONICS INC., Seoul (KR)

(21) Appl. No.: 15/124,544

(22) PCT Filed: Aug. 6, 2014
(86) PCT No.: PCT/KR2014/007263

§ 371 Date: Sep. 8, 2016

Related U.S. Application Data
(60) Provisional application No. 61/954,552, filed on Mar. 17, 2014.

(51) Int. Cl. H04L 1/00; H03M 13/00; H03M 13/11

(52) U.S. Cl. CPC H04L 1/0045; H04L 1/0058; H03M 13/1105; H03M 13/118; H03M 13/616

(57) ABSTRACT

A method for decoding a low density parity check (LDPC) code for forward error correction by a receiver side in a wireless communication system according to an embodiment of the present invention comprises the steps of: acquiring a first reconstructed packet vector by decoding a reception packet vector encoded by an LDPC code generation matrix; determining a candidate for an error packet to be excluded form the reception packet vector when an error is detected in the first reconstructed packet vector; and acquiring a second reconstructed packet vector from the reception packet vector from which the determined candidate for the error packet has been excluded, wherein the step of acquiring the second reconstructed packet vector includes acquiring the second reconstructed packet vector through Gaussian elimination for the LDPC code generation matrix from which a row matrix corresponding to the candidate for the error packet has been excluded.

### TECHNICAL FIELD

The present invention relates to a method and apparatus for decoding a low density parity check (LDPC) code using a maximum likelihood (ML) algorithm so as to allow a reception terminal of a wireless communication system to perform forward error correction (FEC).

### BACKGROUND ART

Error correction for use in a wireless communication system is generally classified into automatic repeat request (ARQ) and forward error correction (FEC), and a hybrid ARQ is a combination of ARQ and FEC.

In accordance with ARQ, if a reception terminal detects an error in a reception packet, the reception terminal explicitly transmits a negative acknowledgement (NACK) message to request retransmission from the transmission terminal. A transmission terminal performs packet retransmission even when the explicit ACK/NACK messages are not received from the reception terminal within a predetermined time. In order to allow the reception terminal to determine the presence or absence of an error in the reception packet, a checksum or cyclic redundancy check (CRC) may be attached to the packet.

In accordance with FEC, the reception terminal may autonomously perform error correction when detecting the error in the reception packet. Since the reception terminal can directly correct the error of the reception packet, the reception terminal may not request retransmission from the transmission terminal. In order to allow the reception terminal to determine the presence or absence of an error in the reception packet as well as to perform error correction, an error correction code (ECC) corresponding to a kind of redundancy may be attached to the packet. As representative examples of ECC generation codes using FEC, a Hamming code, a Bose-Chaudhuri-Hocquenghem (BCH) code, a Reed-Solomon (RS) code, and a low density parity check (LDPC) code, etc. may be used.

In 3GPP LTE, HARQ is used. In 3GPP MBMS (Multimedia Broadcast/Multicast Service), Application Layer Forward Error Correction (AL-FEC) is used. AL-FEC is an error correction method for an application layer, and the 3GPP MBMS protocol stack shown in FIG. 1 includes AL-FEC. FEC for a physical layer may determine ‘0’ or ‘1’ and perform correction on the basis of a probability. In contrast, FEC in the application layer may already be determined to be ‘0’ or ‘1’, or may perform error correction for a blank (or empty) part caused by loss or damage. Accordingly, FEC for the physical layer and FEC for the application layer can be easily distinguished from each other.

In 3GPP MBMS, AL-FEC may use Raptor codes based on LDPC codes. AL-FEC of the 3GPP MBMS system may decode the packet having passed through a UDP protocol. The decoding method of the LDPC codes is broadly classified into a Maximum Likelihood (ML) algorithm and a Message Passing (MP) algorithm.

### DISCLOSURE

### Technical Problem

An object of the present invention is to provide a method for omitting a checksum of at least some packets in a transmission (Tx) layer so as to transmit a packet without retransmission, and a method and apparatus for decoding an LDPC code configured to perform forward error correction (FEC) of a packet error generated by such checksum omission in the application layer.

It will be appreciated by persons skilled in the art that the objects that could be achieved with the present invention are not limited to what has been particularly described hereinabove and the above and other objects that the present invention could achieve will be more clearly understood from the following detailed description.

### Technical Solution

The object of the present invention can be achieved by providing a method for decoding a low density parity check (LDPC) code for forward error correction (FEC) by a reception terminal of a wireless communication system including: acquiring a first reconstructed packet vector by decoding a reception (Rx) packet vector encoded by an LDPC code generation matrix; if an error is detected in the first reconstructed packet vector, determining a candidate of an error packet to be excluded from the Rx packet vector; and acquiring a second reconstructed packet vector from the Rx packet vector from which the determined error packet candidate is excluded, wherein the acquiring the second reconstructed packet vector includes acquiring the second reconstructed packet vector through Gaussian elimination for the LDPC code generation matrix from which a row vector corresponding to the error packet candidate is excluded.

In another aspect of the present invention, an apparatus for decoding a low density parity check (LDPC) code for forward error correction (FEC) of a wireless communication system includes: a receiver configured to receive a reception (Rx) packet vector encoded by an LDPC code generation matrix; and a processor configured to acquire a first reconstructed packet vector by decoding the Rx packet vector, to determine a candidate of an error packet to be excluded from the Rx packet vector if an error is detected in the first reconstructed packet vector, and to acquire a second reconstructed packet vector from the Rx packet vector from which the determined error packet candidate is excluded, wherein the processor is configured to acquire the second reconstructed packet vector through Gaussian elimination for the LDPC code generation matrix from which a row vector corresponding to the error packet candidate is excluded.

### Advantageous Effects

As is apparent from the above description, the wireless communication system according to the embodiments can reduce an End-to-End delay caused by retransmission because a checksum of at least some packets is omitted from a transmission (Tx) layer. Packet error caused by such checksum omission is corrected through forward error correction (FEC) in the application layer, resulting in improvement of Quality of Service (QoS).

It will be appreciated by persons skilled in the art that the effects that can be achieved with the present invention are not limited to what has been particularly described hereinabove and other advantages of the present invention will be more clearly understood from the following detailed description taken in conjunction with the accompanying drawings.

### DESCRIPTION OF DRAWINGS

FIG. 1 is a conceptual diagram illustrating a 3GPP MBMS protocol stack.

FIG. 2 is a conceptual diagram illustrating a wireless communication system according to one embodiment of the present invention.

FIG. 3 is a conceptual diagram illustrating UDP and UDP-Lite acting as exemplary protocols of the protocol applicable to a transmission layer of a wireless communication system.

FIG. 4 is a conceptual diagram illustrating a decoding process based on an ML algorithm.

FIG. 5 is a conceptual diagram illustrating error propagation for the decoding process based on the ML algorithm.

FIGS. 6 to 10 are conceptual diagrams illustrating the decoding processes according to embodiments of the present invention.

FIG. 11 is a flowchart illustrating a decoding method according to an embodiment of the present invention.

FIG. 12 is a block diagram illustrating an apparatus for performing the decoding method according to an embodiment of the present invention.

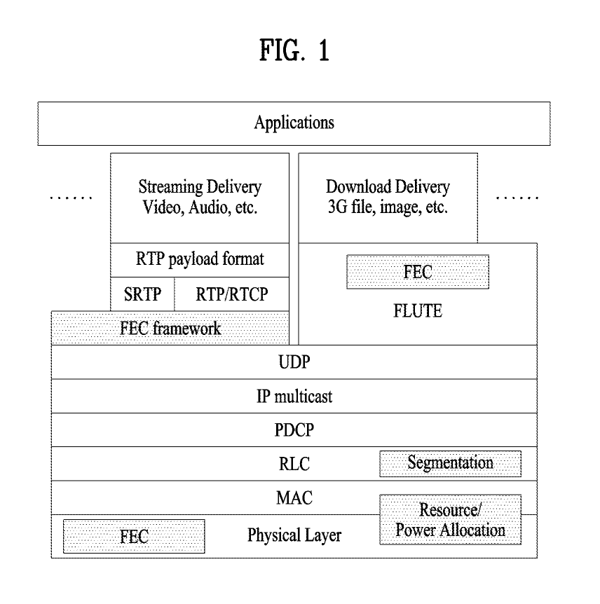

### BEST MODE

Reference will now be made in detail to the preferred embodiments of the present invention, examples of which are illustrated in the accompanying drawings. The detailed description, which will be given below with reference to the accompanying drawings, is intended to explain exemplary embodiments of the present invention, rather than to show the only embodiments that can be implemented according to the present invention. The following detailed description includes specific details in order to provide a thorough understanding of the present invention. However, it will be apparent to those skilled in the art that the present invention may be practiced without such specific details.

In some cases, to prevent the concept of the present invention from being ambiguous, structures and apparatuses of the known art will be omitted, or will be shown in the form of a block diagram based on main functions of each structure and apparatus. Also, wherever possible, the same reference numbers will be used throughout the drawings and the specification to refer to the same or like parts. Specific terminologies hereinafter used in the embodiments of the present invention are provided to assist understanding of the present invention, and various modifications may be made in the specific terminologies within the range that they do not depart from technical spirits of the present invention.

The term ‘LDPC code’ may include a narrow-sense LDPC code and LDPC-based codes each employing a generation matrix. For example, the term ‘LDPC code’ may include the Raptor code and the LT code. Therefore, the embodiments of the present invention can be applied to LDPC-based codes, each of which uses a generation matrix.

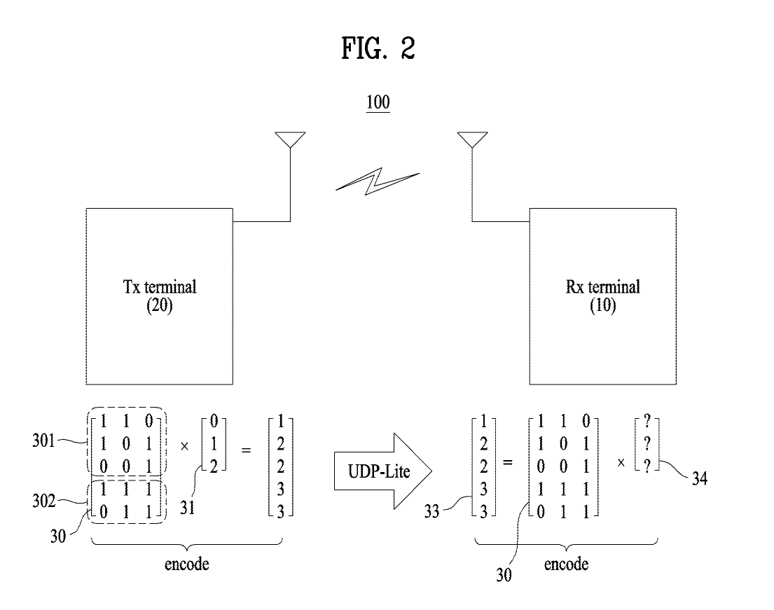

FIG. 2 is a conceptual diagram illustrating a wireless communication system according to one embodiment of the present invention.

Referring to FIG. 2, the wireless communication system 100 may include a transmission (Tx) terminal 20 and a reception (Rx) terminal 10. For example, the wireless communication system 100 may serve as a cellular system or a cellular network, and the following description will be given centering upon a wireless communication system serving as a 3GPP LTE or LTE-A system, but the present invention is not limited thereto and the remaining parts of the present invention other than unique characteristics of the 3GPP LTE or LTE-A system are applicable to the wireless communication system 100 acting as other cellular systems. The following embodiments of the present invention can be applied to a variety of wireless access technologies, for example, CDMA (Code Division Multiple Access), FDMA (Frequency Division Multiple Access), TDMA (Time Division Multiple Access), OFDMA (Orthogonal Frequency Division Multiple Access), SC-FDMA (Single Carrier Frequency Division Multiple Access), and the like. CDMA may be embodied through wireless (or radio) technology such as UTRA (Universal Terrestrial Radio Access) or CDMA2000. TDMA may be embodied through wireless (or radio) technology such as GSM (Global System for Mobile communication)/GPRS (General Packet Radio Service)/EDGE (Enhanced Data Rates for GSM Evolution). OFDMA may be embodied through wireless (or radio) technology such as Institute of Electrical and Electronics Engineers (IEEE) 802.11 (Wi-Fi), IEEE 802.16 (WiMAX), IEEE 802-20, and E-UTRA (Evolved UTRA). UTRA is a part of UMTS (Universal Mobile Telecommunications System). 3GPP (3rd Generation Partnership Project) LTE (long term evolution) is a part of E-UMTS (Evolved UMTS), which uses E-UTRA. 3GPP LTE employs OFDMA in downlink and employs SC-FDMA in uplink. LTE-Advanced (LTE-A) is an evolved version of 3GPP LTE. In addition, the wireless communication system 100 may be a wireless LAN (WLAN) or Wi-Fi system without being limited thereto.

In one embodiment, a receiver 10 or a transmitter 20 may refer to a mobile or fixed user equipment (UE), for example, a terminal, a user equipment (UE), a mobile station (MS), an Advanced Mobile Station (AMS), a station (STA), and the like. In another embodiment, a receiver 10 or the transmitter 20 may refer to an arbitrary node of a wireless communication system which communicates with the above terminal, and may include an eNode B (eNB), a base station (BS), a Node B (Node-B), an access point (AP), a relay, and the like.

The Tx terminal 20 may encode the input packet vector 31 using the LDPC code generation matrix 30, and thus generate a Tx packet vector 32. The Tx terminal 20 may transmit the Tx packet vector 32 to the Rx terminal 10.

The LDPC code generation matrix 30, the input packet vector 31, and the Tx packet vector 32 illustrated in FIG. 2 are disclosed only for illustrative purposes for convenience of description.

The input packet vector 31 may include K input packets. Here, K is an integer of 1 or greater, and denotes the size of the input packet vector 31, where the size K of the input packet vector 31 may be identical to the size of the reconstructed packet vector 34. Each input packet contained in the input packet vector 31 may include a plurality of bits, and may be changed in size in various ways. As can be seen from FIG. 2, the input packets ‘00’, ‘01’, ‘10’ in which k is set to 3 (k=3) and each input packet is expressed as 2 bits are contained in the input packet vector 31.

The LDPC code generation matrix 30 may include N row vectors and K column vectors. Here, N is an integer of K or higher, and N is the size of the Tx packet vector 34 and is identical in size to the Rx packet vector 33. The LDPC code generation matrix 30 may include a (k×k)-sized upper matrix 301 and an ((n−k)×k)-sized lower matrix 392. For convenience of description, the encoding result obtained by the upper matrix 301 will hereinafter be referred to as a data packet, and the encoding result obtained by the lower matrix 302 will hereinafter be referred to as a parity packet. The lower matrix 302 may add the parity packet to the Tx packet vector 32. In the ideal communication environment in which no errors occur, the lower matrix 302 may be omitted as necessary. However, in order to correct errors caused by a poor channel state, the parity packet caused by the lower matrix 302 is needed.

If the Tx terminal 20 encodes the input packet vector 31 including K input packets, the Tx packet vector 32 including N transmission (Tx) packets is output.

The Tx packet vector 32 transmitted from the Tx terminal 20 may be affected by RF-channel noise or the like. The Tx packet vector 32 affected by the RF channel will hereinafter be referred to as a reception (Rx) packet vector 33.

The Tx terminal 10 may acquire the reconstructed packet vector 34 by decoding the Rx packet vector 33. The LDPC code generation matrix 30 is needed to decode the Rx packet vector 33, such that the LDPC code generation matrix 30 may be prestored in the Rx terminal 10. A method for decoding the Rx packet vector using the LDPC code generation matrix 30 using the Rx terminal 10 is largely classified into a Maximum Likelihood (ML) algorithm and a Message Passing (MP) algorithm, and the embodiments of the present invention are based on the ML algorithm.

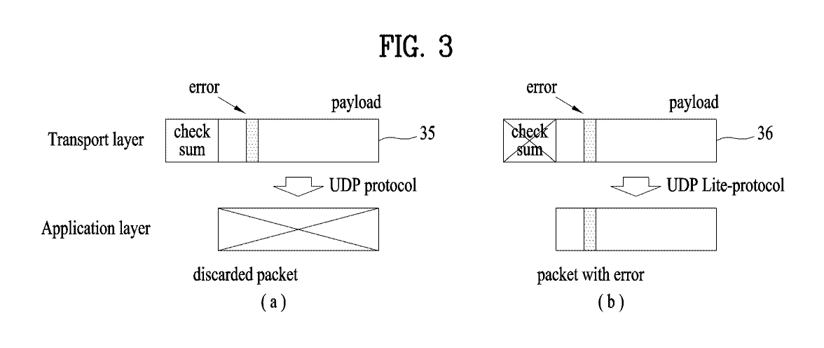

Meanwhile, the UDP or UDL-Lite protocol may be used in the transmission layer for packet transmission between the Tx terminal 20 and the Rx terminal 10. The UDP protocol and the UDP-Lite protocol will hereinafter be described with reference to FIG. 3.

Referring to FIG. 3(a), the reception packet 35 received by the UDP protocol may include a checksum. Errors generated in the transmission process may be detected using the checksum. The Rx packet 35 having such errors may be discarded.

Referring to FIG. 3(b), the UDP-Lite protocol may permit errors of payload of the Rx packet 36. In the case of using the UDP-Lite protocol, at least some packets may not use the checksum. That is, when using the UDP-Lite protocol, the checksum may be used in some packets, and the checksum may not be used in some other packets as necessary. In another embodiment, the checksum for the entire packets may be omitted. The reception (Rx) packet received through the UDP-Lite protocol does not have the checksum, such that the Rx packet is not discarded even when errors exist in the payload and the resultant Rx packet is transmitted to an upper layer.

Although the checksum error occurs, a method for using multimedia data may permit occurrence of some errors, without stopping display of screen images by discarding all the packets, such that noise may be displayed on the screen image even when checksum errors occur in the multimedia data. Therefore, the UDP-Lite protocol may be more appropriate for multimedia data transmission than the UDP protocol. Specifically, although there is a high possibility that a very small number of erroneous symbols occurs in each packet when using a very efficient error correction code in the physical layer, discarding of the entire packet according to the UDP protocol is far from efficient.

Meanwhile, the legacy AL-FEC designed considering the UDP protocol assumes that the Rx packet does not include errors. That is, since the legacy AL-FEC based on the UDP protocol does not have errors in the Rx packet, AL-FEC is very vulnerable to processing of the erroneous Rx packet. Specifically, a combination of the UDP-Lite protocol and the legacy AL-FEC may cause error propagation, such that serious performance deterioration occurs as compared to the other case in which AL-FEC is not used. Therefore, although the legacy AL-FEC process can be temporarily stopped to use the UDP-Lite protocol, it may be preferable that AL-FEC be improved to be more appropriate for the UDP-Lite protocol.

### A. ML Algorithm

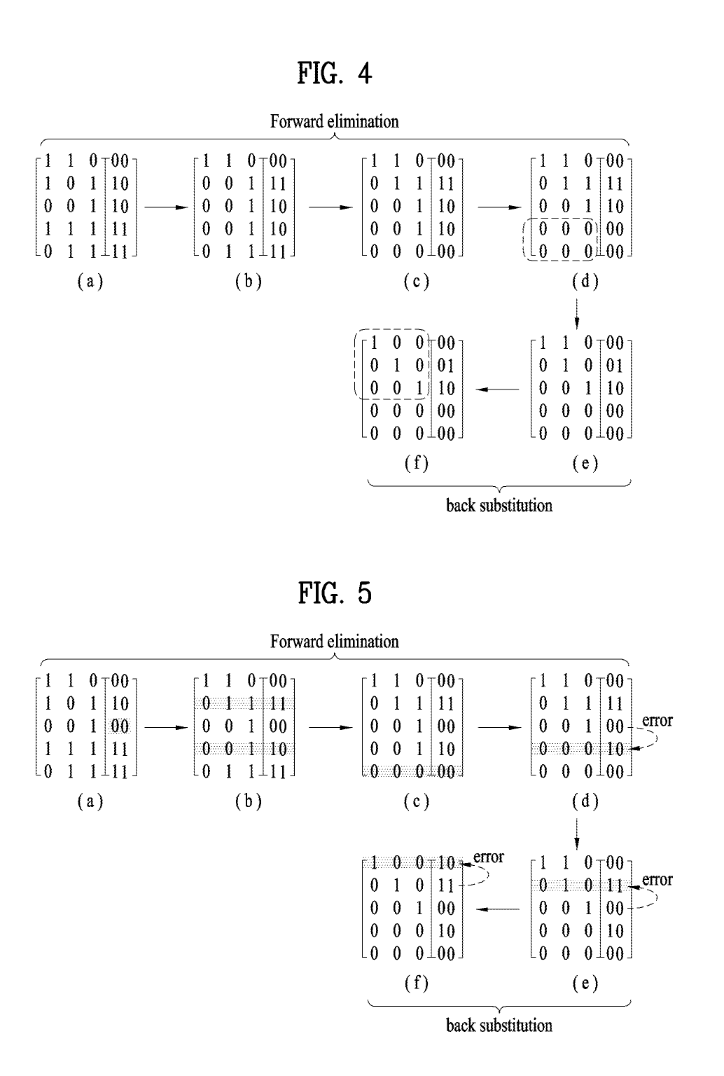

The ML algorithm from among the decoding methods of the DLPC code for AL-FEC will hereinafter be described with reference to FIG. 4.

In the matrix illustrated in FIG. 4(a), three column vectors located at the left part may be the LDPC code generation matrices of FIG. 2, and two column vectors located at the right part may be binary numbers of the Rx packet vector illustrated in FIG. 2. In the following description, R(n) is the N-th row vector, C(m) is the M-th column vector, and [symbol] is defined as a bitwise exclusive OR (XOR) operation. The ML algorithm may be carried out by Gaussian elimination, and may include a forward elimination process and a back substitution process. An XOR operation between vectors (i.e., an inter-vector XOR operation) may be carried out in the forward elimination and the back substitution.

The LDPC code generation matrix is constructed as an upper triangular matrix during forward elimination, and a unit matrix is constructed in the back substitution during back elimination, such that the Rx packet vector is converted into the reconstructed packet vector.

The forward elimination process is performed in the order of the concept of FIG. 4(b)→the concept of FIG. 4(c)→the concept of FIG. 4(d).

FIG. 4(b): R(1) [symbol] R(2), R(1) [symbol] R(4);

FIG. 4(c): R(2) [symbol] R(5);

FIG. (d): R(3) [symbol] R(4)

In order to construct the upper triangular matrix in the forward elimination process, a lower matrix becomes a zero ‘0’ matrix.

The back elimination process is performed in the order of the concept of FIG. 4(e)→the concept of FIG. 4(f).

FIG. 4(e): R(3) [symbol] R(2); FIG. (f): R(2) [symbol] R(1)

In the back substitution result, C(4˜5) indicates that reconstructed packet vectors ‘0’, ‘1’, ‘2’ are acquired. The acquired reconstruction packet vectors may be identical to the input packet vectors 31 of FIG. 2.

Although the embodiment of FIG. 4 assumes that no errors occur in the Rx packet vector, the following description will disclose that errors are contained in the Rx packet vector.

### B. Error Propagation in ML Algorithm

FIG. 5 is a conceptual diagram illustrating error propagation for the decoding process based on the ML algorithm.

Referring to FIG. 5(a), although the R(3) reception (Rx) packet must be denoted by ‘10’, the R(3) reception packet ‘00’ has been received. If the checksum is not used, it is impossible to recognize the occurrence of errors in the Rx packet. Therefore, assuming that the R(3) reception packet has no errors, the ML algorithm of FIG. 5 performs forward elimination and back elimination in the same manner as in FIG. 4.

In FIGS. 5(d) and 5(e) illustrating that R(3) is used in forward elimination and back elimination, errors generated in R(3) are applied to R(4) and errors generated in R(3) are applied to R(2). Therefore, error propagation also occurs in R(1) of FIG. 5(f) in which R(2) is used in the back substitution. As a result, the reconstructed packet vectors [2,3,0] are obtained.

As described above, errors contained in any one Rx packet are propagated to other Rx packets, and the reconstructed packet vector is unavoidably obtained as another value different from the input packet vector.

### C. Protocol in Which Checksum is Not Used

As one example of the protocol used in the transmission (Tx) layer, if the UDP-Lite protocol does not use the checksum, one example of the decoding method according to the ML algorithm will hereinafter be given.

C-1) Error Correction (Validity Verification in the Reconstructed Packet Vector)

A method for detecting errors in the reconstructed packet vector will hereinafter be described.

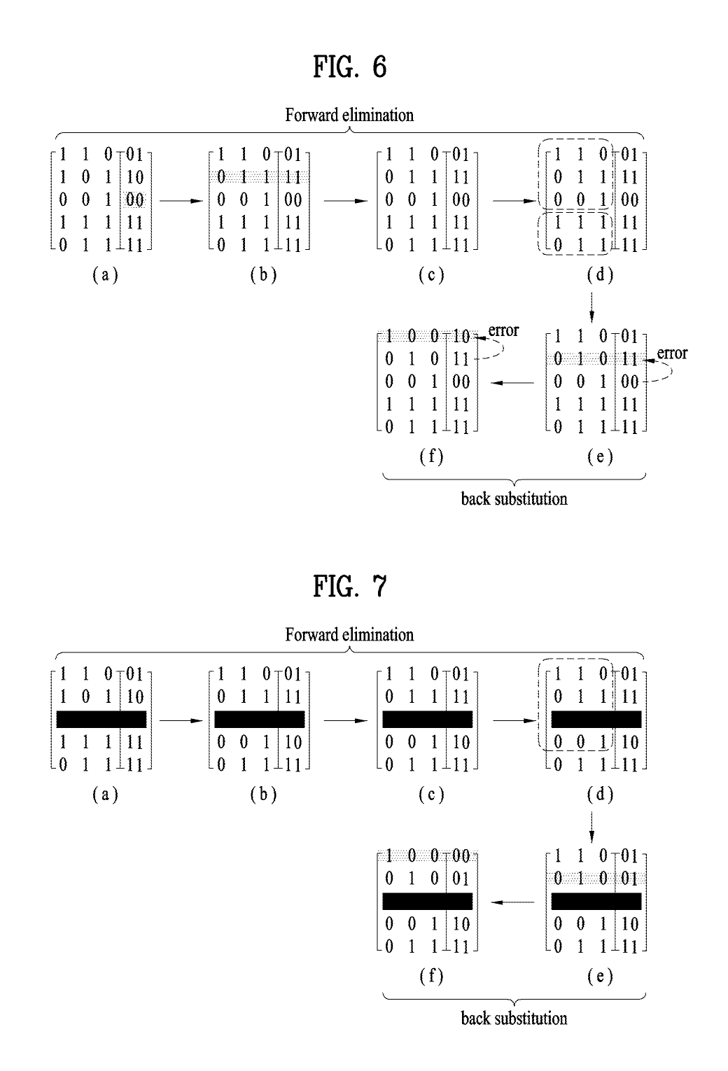

Referring to FIG. 6, errors are present in the R(3) reception packet in the same manner as in the embodiment of FIG. 5. However, the checksum is not used, such that it is impossible for the Rx terminal to recognize the presence or absence of errors in the R(3) reception packet prior to decoding.

Differently from FIG. 5, the forward elimination process and the back substitution process are performed only in the upper matrix and are not performed in the lower matrix as shown in FIG. 6. Therefore, errors encountered in the upper matrix are not propagated to the lower matrix whereas the errors can be propagated to the upper matrix.

According to the forward elimination result, the upper triangular matrix is composed of the upper matrix only as shown in FIG. 6(d). That is, the lower matrix is not converted into a zero ‘0’ matrix. In the back substitution result, the reconstructed packet vector [2,3,0] may be obtained as shown in FIG. 6(e).

The lower matrix may be used to recognize the presence or absence of errors in the reconstructed packet vector. That is, assuming that “R(4)*Reconstructed Packet Vector=[11]” and “R(5)*Reconstructed Packet Vector=[11]” are achieved, it is determined that no errors occur in the reconstructed packet vector. In the embodiment, since “R(4)*[2,3,0]^{T}=5” and “R(5)*[2,3,0]^{T}=3” are achieved, the presence of errors in the reconstructed packet vector is determined through R(4).

Although Gaussian elimination is not performed in the lower matrix according to the embodiment of FIG. 6, Gaussian elimination may be partially performed in the lower matrix according to another embodiment. For example, assuming that Gaussian elimination is performed before a weight of each row of the lower matrix becomes zero, “R(1) [symbol] R(4)=[0, 0, 1]” is achieved and the Rx packet is denoted by [10]. However, since “R(2) [symbol] R(5)=[0, 0, 0]” is obtained and thus the weight becomes zero, R(2) [symbol] R(5) may not be performed. If back substitution is completed, it is possible to recognize the presence or absence of errors in the reconstructed packet vector according to whether or not “R(4)*Reconstructed Packet Vector=[10]” and “R(5)*Reconstructed Packet Vector=[11]” are achieved.

In another embodiment, Gaussian elimination may also be carried out in the lower matrix in the same manner as in the conventional art. For example, if the result of FIG. 5(f) is obtained, it is possible to determine the presence or absence of errors in the reconstructed packet vector according to whether or not “R(4)*Reconstructed Packet Vector=[10]” and “R(5)*Reconstructed Packet Vector=[00]” are achieved.

As described above, if errors are detected in the reconstructed packet vector, the Rx terminal can recognize the presence or absence of errors in at least one Rx packet from among the plurality of Rx packet vectors. However, it is impossible for the Rx terminal to recognize which one of Rx packets includes an error.

C-2) Error Correction

As described above, if errors are detected in the reconstructed packet vector, the Rx terminal may determine a candidate of at least one error packet from among the Rx packet vectors. The Rx terminal may exclude the determined candidate of the error packet from the Rx packet vector. The Rx terminal may exclude a row vector corresponding to a candidate of the determined error packet from the LDPC code generation matrix. Subsequently, the Rx terminal may re-acquire the reconstructed packet vector not only using the Rx packet vector from which the error packet candidate is excluded, but also using the LDPC code generation matrix from which the corresponding row vector is excluded. If no errors are present in the re-acquired reconstructed packet vector, decoding is successfully performed. If errors are also present in the re-acquired reconstructed packet vector, the error packet candidate is changed and decoding is re-performed.

The meaning that the error packet candidate and the row vector corresponding to the error packet candidate are excluded may conceptually include the operations for preventing the error packet candidate and the row vector corresponding to the error packet candidate from being used in decoding. For example, a specific row vector may be deleted or eliminated to exclude a specific row vector. In contrast, a specific row vector is exchanged with another row vector, such that the specific row vector may be located at a lower matrix or the last row.

The candidate of the error packet (i.e., the error packet candidate) may be determined from among the Rx packets used in the ML decoding process. For example, from among the Rx packet vectors [1 2 0 3 3] of FIG. 6(a), the Rx packets used in the forward elimination process or the back substitution process are denoted by [1 2 0], because the Rx packets [3, 3] are not used in the forward elimination process and the back substitution process, but are used to determine the presence or absence of errors in the reconstructed packet vector. Therefore, the error packet candidate may be any one of the vectors [1 2 0].

When deciding the error packet candidate, the weight of a row vector corresponding to each Rx packet may be considered. For example, the Rx packet corresponding to the row vector having a minimum weight may be determined to be the error packet candidate. In FIG. 6(a), R(1) has a weight of 2, R(2) has a weight of 2, and R(3) has a weight of 1, such that a third Rx packet ‘0’ corresponding to R(3) may be determined to be the error packet candidate.

In another embodiment, the Rx packet corresponding to the row vector having a maximum weight may also be determined to be the error packet candidate. For example, as shown in FIG. 6(a), R(1) or R(2) may also be determined to be the error packet candidate.

Referring to FIG. 7, R(3) is excluded from the LDPC code generation matrix, and the third Rx packet ‘0’ corresponding to R(3) is excluded from the Rx packet vector.

In addition, R(4) and the fourth Rx packet, which are not used in decoding, may be used in the forward elimination process and the back substitution process. However, R(5) and the fifth Rx packet are still not used in the forward elimination process and the back substitution process.

According to the decoding result, the reconstructed packet vectors [0, 1, 2] are obtained as shown in FIG. 7(f). Since “R(5)*Reconstructed Packet Vector [0, 1, 2]=3” of FIG. 7(f) is achieved, the Rx terminal may recognize the absence of errors in the reconstructed packet vector. In this way, the Rx terminal may perform error correction.

Meanwhile, assuming that errors are detected in the reconstructed packet vector acquired in FIG. 7(f), the Rx terminal may change the error packet candidate. In this case, the third Rx packet has already been excluded from the decoding process, such that the second Rx packet corresponding to R(2) having a row-vector weight of 2 may be determined to be the error packet candidate. The Rx terminal may exclude R(2) and the second Rx packet, and may re-perform decoding. The Rx terminal changes the error packet candidate and at the same time decoding is repeatedly performed until errors are not detected in the reconstructed packet vector. If errors are detected in the reconstructed packet vector although no more error packet candidates remain, the Rx terminal may determine that decoding has failed. If the decoding failure occurs, any one of the acquired reconstructed packet vectors is randomly selected by previous decoding, such that the selected vectors are supplied to an upper layer.

### D. Protocol Configured to Use the Checksum in Some Packets

As an example of the case in which the checksum is used in some packets, an exemplary case in which errors are detected through the checksum in the packet having the checksum will hereinafter be described.

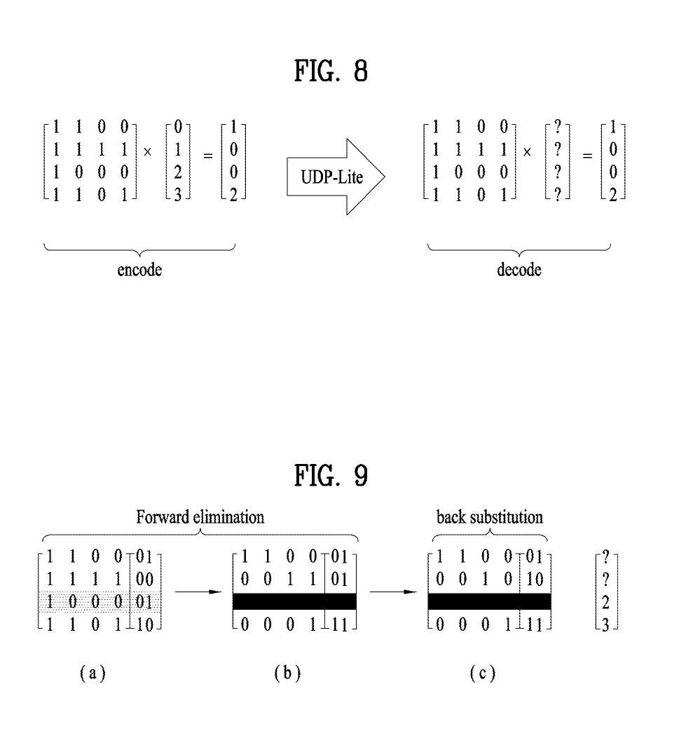

Referring to FIG. 8, the Tx terminal may transmit the Tx packet vectors [1, 0, 0, 2]. However, since errors occur in the third packet, the Rx terminal may receive the Rx packet vectors [1, 0, 1, 2]. In addition, the checksum is used in the third Rx packet, such that the Rx terminal detects the presence of errors in the third Rx packet.

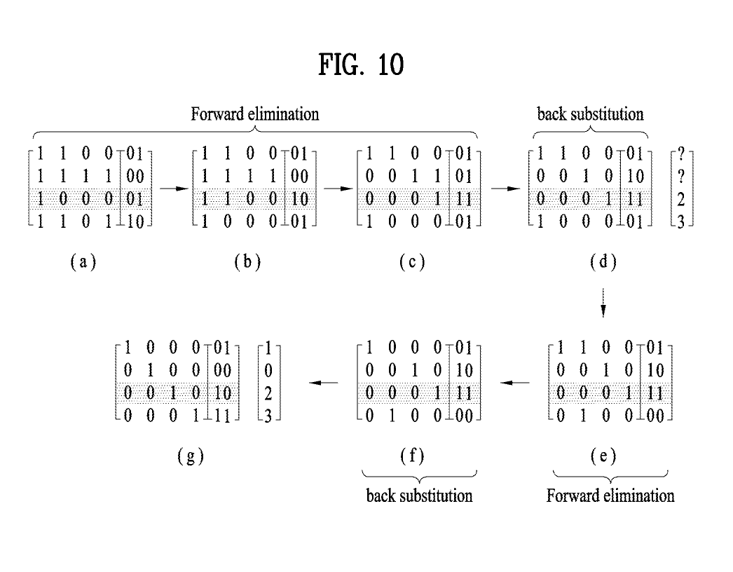

FIG. 9 is a conceptual diagram illustrating the decoding process based on the legacy ML algorithm. In accordance with the legacy ML algorithm, the third Rx packet has errors so that it is discarded. The result obtained when the forward elimination process and the back substitution process are performed after the third Rx packet is discarded is shown in FIG. 9(c). Since the third Rx packet and R(3) corresponding to the third Rx packet are discarded, the first reconstructed packet and the second reconstructed packet cannot be decoded in the reconstructed packet vector as shown in FIG. 9(c). However, the correct decoding result can be obtained from the third and fourth reconstructed packets.

Assuming that multimedia data is used, a still image will be displayed on the part corresponding to the first and second reconstructed packets, such that more serious performance deterioration occurs as compared to the other case in which a display image having noise is output.

FIG. 10 is a conceptual diagram illustrating a decoding process based on the ML algorithm according to another embodiment. Instead of discarding the third Rx packet having errors, the Rx terminal may move the third Rx packet to the last position as shown in FIG. 10(b), and may exchange the row vector of R(3) with the other row vector of R(4).

Subsequently, the Rx terminal may perform forward elimination and back substitution. In the forward elimination process and the back substitution process, the Rx terminal may perform decoding on the remaining parts other than the Rx packet having errors and the row vector corresponding to the erroneous Rx packet. As illustrated in FIG. 10(d), the third and fourth reconstructed packets are obtained, and the first and second reconstructed packets are not obtained.

If a non-reconstructed packet exists, the Rx terminal may perform forward elimination and back substitution for (R1) and R(4) using an erroneous Rx packet and the row vector corresponding to the erroneous Rx packet, as illustrated in FIGS. 10(e) and 10(f). Subsequently, if row vector exchange is performed as shown in FIG. 10(g), the reconstructed packet vectors [1, 0, 2, 3] are obtained according to the decoding result. When the reconstructed packet vectors are compared with the input packet vectors [0, 1, 2, 3], although some noise is included in the first packet and the second packet, the case of permitting some errors causing a noisy screen image is preferable to the other case of discarding the entire packet. In more detail, although the Rx packet includes one or more errors on a packet basis, this Rx packet includes normal symbols having no errors, such that the case of permitting some errors is considered more preferable.

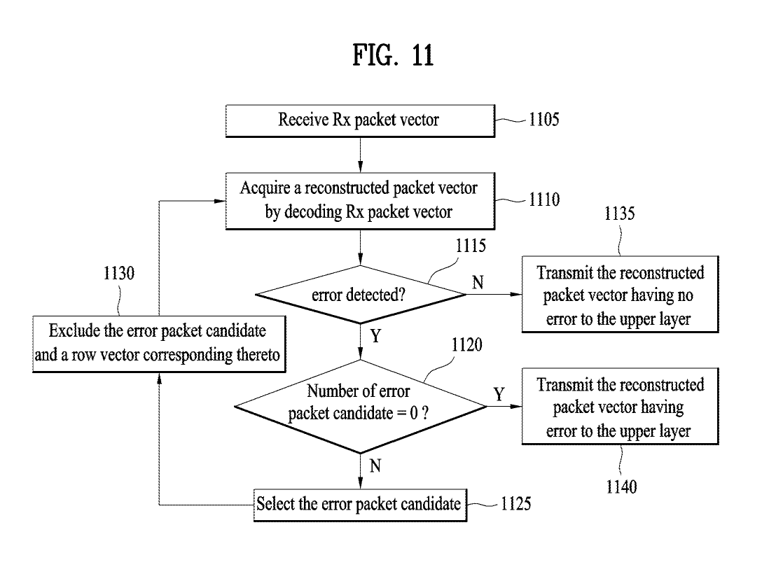

FIG. 11 is a flowchart illustrating a decoding method according to an embodiment of the present invention. The same content as in the above-mentioned embodiment will herein be omitted for convenience of description.

Referring to FIG. 11, the Rx terminal may receive the Rx packet vectors from the Tx terminal in step 1105.

The Rx terminal may decode the Rx packet vector, and may thus acquire the first reconstructed packet vector in step 1110. For example, the Rx terminal may perform forward elimination in a manner that only the upper matrix contained in the LDPC code generation matrix composed of the (k×k)-sized upper matrix and the ((n−k)×k)-sized lower matrix can construct the upper triangular matrix. The Rx terminal may perform back substitution on the above upper matrix composed of the upper triangular matrix, and thus acquire the first reconstructed packet vector. In this case, n may be the number of Rx packets contained in the Rx packet vector, and k may be the number of reconstructed packets contained in the first reconstructed packet vector.

The Rx terminal may determine the presence or absence of one or more errors in the first reconstructed packet vector in step 1115. For example, the Rx terminal may determine the presence or absence of one or more errors in the first reconstructed packet vector using Rx packets that are not used in the back substitution process of Gaussian elimination in the decoding process of the above Rx packet vector performed to obtain the first reconstructed packet vector.

If no errors are detected, the Rx terminal may transmit the first reconstructed packet vector having no errors to the upper layer in step 1135.

If errors are detected, the Rx terminal may determine whether the number of candidates of the error packet is set to zero ‘0’ in step 1120. For example, through repeated decoding, it is determined whether error packet candidates to be excluded are not present any more, or it is determined whether other error packet candidates are present. If each of all Rx packets has already been selected as such error packet candidate at least once, the number of error packet candidates becomes zero ‘0’.

If the number of error packet candidates is not zero, the Rx terminal may select a candidate of at least one error packet to be excluded from the Rx packet vector in step 1125. The Rx terminal may determine the candidate of the error packet on the basis of the weight of each row vector contained in the LDPC code generation matrix. For example, this error packet candidate may include the Rx packet corresponding to a row vector having a minimum weight from among row vectors, each of which has not been excluded from the LPDC code generation matrix.

In addition, the Rx terminal may select the candidate of an error packet from among the Rx packets which are not used in the back substitution process of Gaussian elimination in the decoding process of the Rx packet vector performed to obtain the first reconstructed packet vector.

In the meantime, at least one Rx packet among the Rx packet vectors may be received through the UDP-Lite protocol without using the checksum. In this case, from among the plurality of Rx packets having the checksum, any one of the Rx packet having the checksum error and the other Rx packet having no checksum may be determined as the above error packet candidate.

The Rx terminal may exclude the row vector corresponding to the error packet candidate in step 1130, and may acquire the second reconstructed packet vector through execution of the decoding process in step 1110. The Rx terminal may acquire the second reconstructed packet vector through Gaussian elimination for the LDPC code generation matrix from which the row vector corresponding to the error packet candidate is excluded.

As described above, if one or more errors are detected in the reconstructed packet vector, the Rx terminal may recursively perform the above steps 1120, 1125, 1130, 1110, and 1115. As a result, the Rx terminal may re-determine the candidate of the error packet, and may re-acquire the reconstructed packet vector on the basis of the redetermined error packet candidate.

If one or more errors are detected in each of all the re-determined reconstructed packet vectors, the Rx terminal may provide any one second reconstructed packet vector randomly selected from among the redetermined second reconstructed packet vectors to the upper layer in step 1140. For example, assuming that the process for obtaining the reconstructed packet vector having no errors fails until all the error packet candidates are consumed, the reconstructed packet vector having errors may be selected at random and then provided to the upper layer.

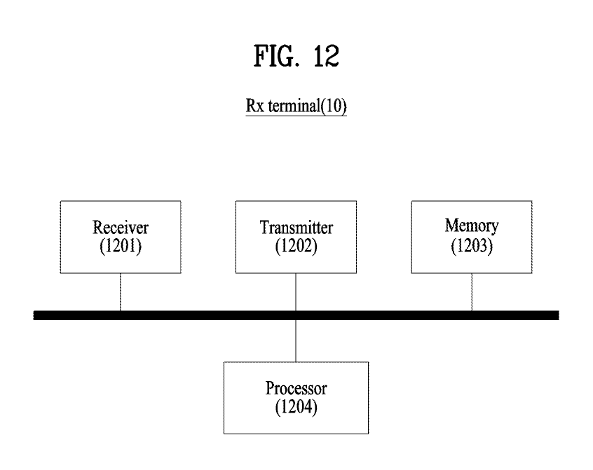

FIG. 12 is a block diagram illustrating an apparatus for performing the decoding method according to an embodiment of the present invention. The same elements as in the above-mentioned embodiments will not be described herein for clarity.

Referring to FIG. 12, the Rx terminal 10 may include a receiver 1201, a transmitter 1202, a memory 1203, and a processor 1204. However, not all the illustrated constituent elements are requisite for the Rx terminal 10. In addition, universal constituent elements not illustrated in the Rx terminal 10 may further be included as necessary.

The receiver 1201 may receive the Rx packet vector encoded by the LDPC code generation matrix.

The memory 1203 may store the LDPC code generation matrix and the Rx packet vector.

The processor 1204 may acquire the first reconstructed packet vector by decoding the Rx packet vector. If one or more errors are detected in the first reconstructed packet vector, the processor 1204 may determine the candidate of the error packet to be excluded from the Rx packet vector. The processor 1204 may acquire the second reconstructed packet vector from the Rx packet vector from which the determined error packet candidate is excluded. The processor 1204 may acquire the second reconstructed packet vector through Gaussian elimination of the LDPC code generation matrix from which the row vector corresponding to the error packet candidate is excluded.

The processor 1204 may determine the error packet candidate on the basis of the weight of each row vector of the LDPC code generation matrix. The determined error packet candidate may be the Rx packet corresponding to the row vector having a minimum weight from among the row vectors that have not been excluded from the LPDC code generation matrix.

The processor 1204 may select the candidate of the error packet from among the Rx packets not used in back substitution of Gaussian elimination during the decoding process of the Rx packet vectors processed to obtain the first reconstructed packet vector.

The processor 1204 may perform forward elimination in a manner that only the upper matrix contained in the LDPC code generation matrix composed of the (k×k)-sized upper matrix and the ((n−k)×k)-sized lower matrix can construct the upper triangular matrix. The processor 1204 may perform back substitution on the above upper matrix composed of the upper triangular matrix, and thus acquire the first reconstructed packet vector. In this case, n may be the number of Rx packets contained in the Rx packet vector, and k may be the number of reconstructed packets contained in the first reconstructed packet vector. The row vector corresponding to the error packet candidate may be located at the upper matrix.

If the error is detected in the second reconstructed packet vector, the processor 1204 may recursively perform the process for determining the error packet candidate and the process for acquiring the second reconstructed packet vector. The processor 1204 may re-determine the error packet candidate, and may re-acquire the second reconstructed packet vector on the basis of the redetermined error packet candidate. If one or more errors are detected in all the redetermined second reconstructed packet vectors, the processor 1204 may provide the upper layer with one second reconstructed packet vector having been randomly selected.

The receiver 1201 may receive at least one Rx packet from among the Rx packet vectors through the UDP-Lite protocol without using the checksum. The processor 1204 may determine any one of the Rx packets having a checksum error from among the plurality of Rx packets having a checksum and the other Rx packet having no checksum to be the candidate of the error packet (i.e., error packet candidate).

The above-mentioned embodiments have disclosed the encoding and decoding process of the LDPC code on the basis of the LDPC code generation matrix. In the case of FED in the physical layer, LDPC codes are mainly disclosed from the viewpoint of the decoder. In the case of FEC in the physical layer, LDPC codes are mainly disclosed for the viewpoint of the decoder. Therefore, LDPC code decoding is generally disclosed on the basis of the parity check matrix used in the decoder. However, in the case of FEC in the application layer, LDPC codes are disclosed from the viewpoint of the encoder. Therefore, the embodiments of the present invention have disclosed LDPC code decoding on the basis of the LDPC code generation matrix used in the encoder. The generation matrix and the parity check matrix may indicate the LDPC code structure for use in the Tx terminal and the Rx terminal. Whereas it is very easy to explain the decoder using the parity check matrix, it is very difficult to explain the encoder using the parity check matrix. In contrast, the LDPC code generation matrix can be easily explained using the encoder and the decoder, such that the embodiments of the present invention have been disclosed on the basis of the LDPC code generation matrix. However, the decoding process based on the parity check matrix is not excluded from the scope or spirit of the present invention. Therefore, the decoding methods based on the LDPC code generation matrix according to the present invention may also be replaced with other decoding methods based on the parity check matrix within the equivalent ranges of the present invention.

The above-described embodiments of the present invention can be implemented by a variety of means, for example, hardware, firmware, software, or a combination thereof.

In the case of implementing the present invention by hardware, the present invention can be implemented with application specific integrated circuits (ASICs), Digital signal processors (DSPs), digital signal processing devices (DSPDs), programmable logic devices (PLDs), field programmable gate arrays (FPGAs), a processor, a controller, a microcontroller, a microprocessor, etc.

If operations or functions of the present invention are implemented by firmware or software, the present invention can be implemented in the form of a variety of formats, for example, modules, procedures, functions, etc. Software code may be stored in a memory to be driven by a processor. The memory may be located inside or outside of the processor, so that it can communicate with the aforementioned processor via a variety of well-known parts.

The detailed description of the exemplary embodiments of the present invention has been given to enable those skilled in the art to implement and practice the invention. Although the invention has been described with reference to the exemplary embodiments, those skilled in the art will appreciate that various modifications and variations can be made in the present invention without departing from the spirit or scope of the invention described in the appended claims. For example, those skilled in the art may use each construction described in the above embodiments in combination with each other. Accordingly, the invention should not be limited to the specific embodiments described herein, but should be accorded the broadest scope consistent with the principles and novel features disclosed herein.

Those skilled in the art will appreciate that the present invention may be carried out in other specific ways than those set forth herein without departing from the spirit and essential characteristics of the present invention. The above exemplary embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein. Also, it will be obvious to those skilled in the art that claims that are not explicitly cited in the appended claims may be presented in combination as an exemplary embodiment of the present invention or included as a new claim by subsequent amendment after the application is filed.

### INDUSTRIAL APPLICABILITY

The embodiments of the present invention as described above are applicable to various mobile communication systems.

1. A method for decoding a low density parity check (LDPC) code for forward error correction (FEC) by a reception terminal of a wireless communication system, the method comprising:
acquiring a first reconstructed packet vector by decoding a reception (Rx) packet vector encoded by an LDPC code generation matrix;
if an error is detected in the first reconstructed packet vector, determining a candidate of an error packet to be excluded from the Rx packet vector; and
acquiring a second reconstructed packet vector from the Rx packet vector from which the determined error packet candidate is excluded,
wherein the acquiring the second reconstructed packet vector includes
acquiring the second reconstructed packet vector through Gaussian elimination for the LDPC code generation matrix from which a row vector corresponding to the error packet candidate is excluded.

2. The method according to claim 1, wherein the determining the error packet candidate includes:
determining the error packet candidate based on a weight of each row vector contained in the LDPC code generation matrix.

3. The method according to claim 2, wherein the determined error packet candidate corresponds to a Rx packet corresponding to a row vector having a minimum weight among a plurality of row vectors not having history indicating that each row vector was excluded from the LDPC code generation matrix.

4. The method according to claim 1, wherein the determining the error packet candidate includes:
selecting the error packet candidate from among Rx packets not used in back substitution of Gaussian elimination in a decoding process of the Rx packet vector processed to acquire the first reconstructed packet vector.

5. The method according to claim 1, further comprising:
determining whether an error is the present in the first reconstructed packet vector, by using reception packets not used in back substitution of Gaussian elimination in a decoding process of the Rx packet vector processed to acquire the first reconstructed packet vector.

6. The method according to claim 1, wherein the acquiring the first reconstructed packet vector includes:
performing forward elimination in a manner that, in the LDPC code generation matrix composed of a (k×k)-sized upper matrix and an ((n−k)×k)-sized lower matrix, only the upper matrix constructs an upper triangular matrix; and
acquiring the first reconstructed packet vector by performing back substitution on the upper matrix composed of the upper triangular matrix,
wherein n is a number of Rx packets contained in a Rx packet vector, and k is a number of reconstructed packets contained in the first reconstructed packet vector.

7. The method according to claim 6, wherein the determining the candidate of the error packet includes:
determining the error packet candidate in a manner that a row vector corresponding to the error packet candidate is located at the upper matrix.

8. The method according to claim 1, wherein:
if an error is detected in the second reconstructed packet vector, the determining the error packet candidate and the acquiring the second reconstructed packet vector are recursively performed, such that the error packet candidate is redetermined and the second reconstructed packet vector is re-acquired based on the redetermined error packet candidate.

9. The method according to claim 8, further comprising:
if the error is detected in each of the second reconstructed packet vectors after the determining the error packet candidate and the acquiring the second reconstructed packet vector are recursively performed,
providing one second reconstructed packet vector randomly selected from among the redetermined second reconstructed packet vectors to an upper layer.

10. The method according to claim 1, wherein at least one Rx packet from among the Rx packet vectors is received through a UDP-Lite protocol without having a checksum.

11. The method according to claim 10, wherein the determining the candidate of the error packet includes:
determining any one of a Rx packet having a checksum error from among a plurality of Rx packets having the checksum and a Rx packet having no checksum to be the candidate of the error packet.

12. An apparatus for decoding a low density parity check (LDPC) code for forward error correction (FEC) of a wireless communication system, the apparatus comprising:
a receiver configured to receive a Rx packet vector encoded by an LDPC code generation matrix; and
a processor configured to acquire a first reconstructed packet vector by decoding the Rx packet vector, to determine a candidate of an error packet to be excluded from the Rx packet vector if an error is detected in the first reconstructed packet vector, and to acquire a second reconstructed packet vector from the Rx packet vector from which the determined error packet candidate is excluded,
wherein the processor is configured to acquire the second reconstructed packet vector through Gaussian elimination for the LDPC code generation matrix from which a row vector corresponding to the error packet candidate is excluded.

13. The apparatus according to claim 12, wherein:
the processor is configured to determine the error packet candidate based on a weight of each row vector contained in the LDPC code generation matrix,
wherein the determined error packet candidate corresponds to a Rx packet corresponding to a row vector having a minimum weight from among a plurality of row vectors not having history indicating that each row vector was excluded from the LDPC code generation matrix.

14. The apparatus according to claim 12, wherein the processor is configured to select the error packet candidate from among Rx packets not used in back substitution of Gaussian elimination in a decoding process of the Rx packet vector processed to acquire the first reconstructed packet vector.

15. The apparatus according to claim 12, wherein:
the processor performs forward elimination in a manner that, in the LDPC code generation matrix composed of a (k×k)-sized upper matrix and an ((n−k)×k)-sized lower matrix, only the upper matrix constructs an upper triangular matrix, and acquires the first reconstructed packet vector by performing back substitution on the upper matrix composed of the upper triangular matrix,
wherein n is a number of Rx packets contained in a Rx packet vector, and k is a number of reconstructed packets contained in the first reconstructed packet vector; and
the row vector corresponding to the error packet candidate is located at the upper matrix.

16. The apparatus according to claim 12, wherein:
the processor, if an error is detected in the second reconstructed packet vector, is configured to recursively perform a process of determining the error packet candidate and a process of acquiring the second reconstructed packet vector, to re-determine the error packet candidate, and to re-acquire the second reconstructed packet vector based on the redetermined error packet candidate; and
the processor, if the error is detected in each of the redetermined second reconstructed packet vectors after the process of determining the error packet candidate and the process of acquiring the second reconstructed packet vector are recursively performed, is configured to provide one second reconstructed packet vector randomly selected from among the redetermined second reconstructed packet vectors to an upper layer.

17. The apparatus according to claim 12, wherein:
the receiver is configured to receive at least one Rx packet from among the Rx packet vectors through a UDP-Lite protocol without having a checksum; and
the processor is configured to determine any one of a Rx packet having a checksum error from among a plurality of Rx packets having the checksum and a Rx packet having no checksum to be the candidate of the error packet.
